(19) United States
(12) Patent Application Publication
(10) Pub. No.: US 2024/0072733 A1
(43) Pub. Date: Feb. 29, 2024

(54) Distributed Amplifier

(71) Applicant: NIPPON TELEGRAPH AND TELEPHONE CORPORATION, Tokyo (JP)

(72) Inventors: Teruo Jo, Tokyo (JP); Munehiko Nagatani, Tokyo (JP); Hideyuki Nosaka, Tokyo (JP)

(21) Appl. No.: 18/256,022

(22) PCT Filed: Dec. 17, 2020
(86) PCT No.: PCT/JP2020/047148

§ 371 Date: Jun. 23, 2023

(51) Int. Cl. H03F 1/22; H03F 3/60

(52) U.S. Cl. CPC H03F 1/223; H03F 3/604; H03F 3/605

(57) ABSTRACT

A unit amplifier has first and second transistors, which are cascode-connected, and a first variable resistance circuit. A base terminal or a gate terminal of the first transistor is connected to a cell input terminal, a collector terminal or a drain terminal of the second transistor is connected to a cell output terminal, an emitter terminal or a source terminal of the second transistor is connected to a collector terminal or a drain terminal of the first transistor, and one end of the first variable resistance circuit is connected to a connecting point of the first and second transistors.

### CROSS-REFERENCE TO RELATED APPLICATIONS

This application is a national phase entry of PCT Application No. PCT/JP2020/047148, filed on Dec. 17, 2020, which application is hereby incorporated herein by reference.

### TECHNICAL FIELD

The present invention relates to a distributed amplifier having a variable gain function.

### BACKGROUND

In general, various systems such as high-speed communication and high-resolution radars are required to provide a wide-band amplifier having good amplification characteristics in a wide frequency band.

In related art, a distributed amplifier 50 as shown in FIG. 16 has been proposed in NPL 1 as technology for widening the band of the amplifier. FIG. 16 is a block diagram showing a configuration of a distributed amplifier of the related art. In the distributed amplifier 50, a plurality of unit amplifiers AMP are connected in a ladder shape between an input side transmission line W51 and an output side transmission line W52. The unit amplifier AMP is made up of an input transistor Qi and an output transistor Qo which are cascode-connected.

In the related art of NPL 1, a parasitic capacitance of a transistor constituting the unit amplifier AMP is incorporated into the input side transmission line W51 and the output side transmission line W52 to achieve impedance matching. Further, the related art enables wide-band signal amplification by matching propagation constants between the input side transmission line W51 and the output side transmission line W52.

Usually, an amplifier is required to have a variable gain function to compensate for variations in gain and frequency characteristics of a chip and a system. In the related art, as a method for realizing a variable gain, there is a technique for changing a terminating resistance (output load resistance) proposed in NPL 2, or a technique for adjusting the bias of an input transistor proposed in NPL 3.

### CITATION LIST

### Non Patent Literature

NPL 1—Eriksson, Klas, Izzat Darwazeh, and Herbert Zirath. “InP DHBT distributed amplifiers with up to 235-GHz bandwidth.” IEEE Transactions on Microwave Theory and Techniques 63.4 (2015): 1334-1341.
NPL 2—S. Nakano et al., “A 2.25-mW/Gb/s 80-Gb/s-PAM4 linear driver with a single supply using stacked current-mode architecture in 65-nm CMOS,” 2017 Symposium on VLSI Circuits, Kyoto, 2017, pp. C322-C323, doi: 10.23919/VLSIC.2017.8008525.

NPL 3—Sadhu, B., J. F. Bulzacchelli, and A. Valdes-Garcia. “A 28 GHz SiGe BiCMOS phase invariant VGA.” 2016 IEEE Radio Frequency Integrated Circuits Symposium (RFIC). IEEE, 2016.

### SUMMARY

### Technical Problem

However, such methods of realizing a variable gain in the related art have the following problems. When the technique of NPL 2 is applied to the unit amplifier AMP of FIG. 16 and the gain is made variable by changing the resistance value of the terminating resistance Rc of the output transmission line W52, impedance mismatching occurs between the output transmission line W52 and the terminating resistance Rc, and multiple reflection occurs. As a result, there is a problem that a ripple is generated in the frequency characteristic, and a desired characteristic cannot be obtained.

FIG. 17 is a graph showing a simulation result (when adjusting the terminating resistance value) of an S parameter S21 of the unit amplifier of the related art, where a characteristic A shows a low gain setting time and a characteristic B shows a high gain setting time. As shown by the characteristic A in FIG. 17, when the value of the terminating resistance Re is reduced at the low gain setting time, the DC gain changes, but the gain on the high-frequency side does not substantially change, and it can be confirmed that ripples are generated on the high-frequency side.

Further, when the technique of NPL 3 is applied to the unit amplifier AMP of FIG. 16 and the bias voltage Vbin of the input transistor Qi of the unit amplifier AMP is changed to make the gain variable, there is a problem that the band characteristic deteriorates. This is because, in general, the transistor has an optimal bias point (bias current and bias voltage) that operates earliest (ft and fmax become highest), and when an actual bias condition deviates from the optimal bias point, the operating speed of the transistor decreases.

FIG. 18 is a graph showing a simulation result (bias voltage value adjustment time) of the S parameter S21 of the unit amplifier of the related art. FIG. 18 is a graph showing the simulation result (bias voltage value adjustment time) of the S parameter S21 of the unit amplifier of the related art, where the characteristic A shows the low gain setting time and the characteristic B shows the high gain setting time. As shown by the characteristics A and B in FIG. 18, when the bias voltage Vbin is changed at the low gain setting time, it can be confirmed that the gain decreases and the band also deteriorates.

Embodiments of the present invention are intended to solve such a problem, and an object of the present invention is to provide a distributed amplifier which can change a gain without significantly deteriorating band characteristics.

### Solution to Problem

In order to achieve such an object, a distributed amplifier according to embodiments of the present invention includes an input side transmission line configured such that an input signal is input to one end and an input side terminating resistance is connected to the other end; an output side transmission line configured such that an output side terminating resistance is connected to one end and an output signal is output from the other end; and a plurality of unit amplifiers which are disposed parallel with each other along the input side transmission line and the output side transmission line in a ladder shape, and in which a cell input terminal is connected to the input side transmission line and a cell output terminal is connected to the output side transmission line, in which the unit amplifiers include first and second transistors that are cascode-connected, and a first variable resistance circuit, a base terminal or a gate terminal of the first transistor is connected to the cell input terminal, a collector terminal or a drain terminal of the second transistor is connected to the cell output terminal, an emitter terminal or a source terminal of the second transistor is connected to the collector terminal or the drain terminal of the first transistor, and one end of the first variable resistance circuit is connected to a connecting point of the first and second transistors.

Another distributed amplifier according to embodiments of the present invention includes a front amplifier block which is made up of the distributed amplifier described above, amplifies an input signal that is input, and outputs an obtained intermediate signal; and a rear amplifier block which is made up of the distributed amplifier described above, amplifies the intermediate signal output from the front amplifier block, and outputs an obtained output signal, in which a power supply voltage applied to an output side transmission line of the front amplifier block via an output side terminating resistance has a voltage value equal to the sum of a both-end voltage of the output side terminating resistance and a bias voltage applied to an input side transmission line of the rear amplifier block via an input side terminating resistance, and the both-end voltage is made up of a product of a current flowing through the output side terminating resistance and a resistance value of the output side terminating resistance, when a DC potential of an output terminal of the front amplifier block is equal to the bias voltage.

Another distributed amplifier according to embodiments of the present invention includes a front amplifier block which is made up of the distributed amplifier described above, amplifies an input signal that is input, and outputs an obtained intermediate signal; and a rear amplifier block which is made up of the distributed amplifier described above, amplifies the intermediate signal output from the front amplifier block, and outputs an obtained output signal, in which a power supply voltage applied to an output side transmission line of the front amplifier block via an output side terminating resistance has a voltage value equal to the sum of a both-end voltage of the output side terminating resistance and a bias voltage applied to an input side transmission line of the rear amplifier block via the input side terminating resistance, the both-end voltage is made up of a product of a current flowing through the output side terminating resistance and a resistance value of the output side terminating resistance, when a DC potential of an output terminal of the front amplifier block is equal to the bias voltage, and when the first adjustment voltage is changed at the time of changing the gain, a power supply voltage made up of a new DC voltage value, which is equal to the sum of the product of the current flowing through the output side terminating resistance and the resistance value of the output side terminating resistance, and the bias voltage applied to the input side transmission line of the rear amplifier block, is applied to the output side transmission line of the front amplifier block.

### Advantageous Effects of Embodiments of the Invention

According to embodiments of the present invention, the gain of the distributed amplifier can be changed without significantly deteriorating the band characteristic.

### BRIEF DESCRIPTION OF THE DRAWINGS

FIG. 1 is a block diagram showing a configuration of a distributed amplifier according to a first embodiment.

FIG. 2 is a circuit diagram showing the configuration of a unit amplifier according to the first embodiment.

FIG. 3 is a graph showing simulation results of an S parameter S21 of the unit amplifier according to the first embodiment.

FIG. 4 is a circuit diagram showing a configuration of a unit amplifier according to a second embodiment.

FIG. 5 is a graph showing simulation results of the S parameter S21 of the unit amplifier according to the second embodiment.

FIG. 6 is a block diagram showing a configuration of a distributed amplifier according to a third embodiment.

FIG. 7 is a circuit diagram showing the configuration of the unit amplifier (front amplifier block) according to the third embodiment.

FIG. 8 is a circuit diagram showing a configuration of a unit amplifier (rear amplifier block) according to the third embodiment.

FIG. 9 is a graph showing simulation results of the S parameter S21 of the unit amplifier according to the third embodiment.

FIG. 10 is a circuit diagram showing a configuration of a distributed amplifier according to a fourth embodiment.

FIG. 11 is a circuit diagram showing a variable resistance circuit according to a fifth embodiment.

FIG. 12 is a circuit diagram showing a variable resistance circuit according to a sixth embodiment.

FIG. 13 is a Smith chart showing simulation results of the S parameter S11 viewed from a connecting point N of the variable resistance circuit according to the sixth embodiment.

FIG. 14 is a circuit diagram showing a configuration of a unit amplifier (front amplifier block) according to a seventh embodiment.

FIG. 15 is a circuit diagram showing the configuration of the unit amplifier (rear amplifier block) according to the seventh embodiment.

FIG. 16 is a block diagram showing a configuration of a distributed amplifier of the related art.

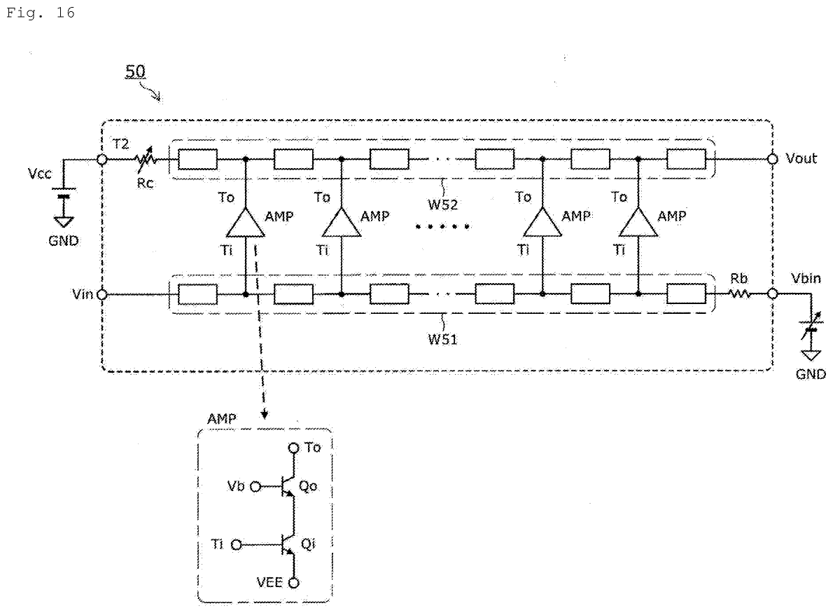

FIG. 17 is a graph showing a simulation result (a terminating resistance value adjustment time) of an S parameter S21 of a unit amplifier of the related art.

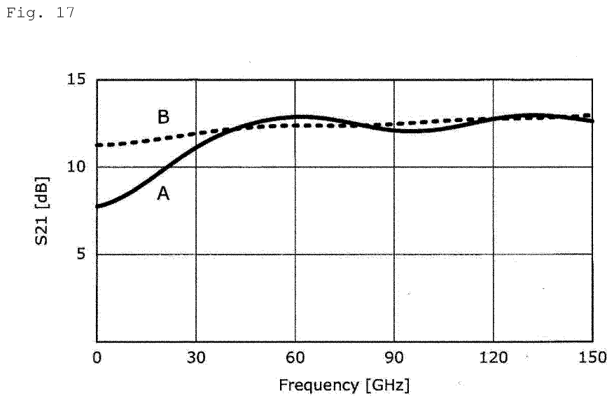

FIG. 18 is a graph showing the simulation result (bias voltage value adjustment time) of the S parameter S21 of the unit amplifier of the related art.

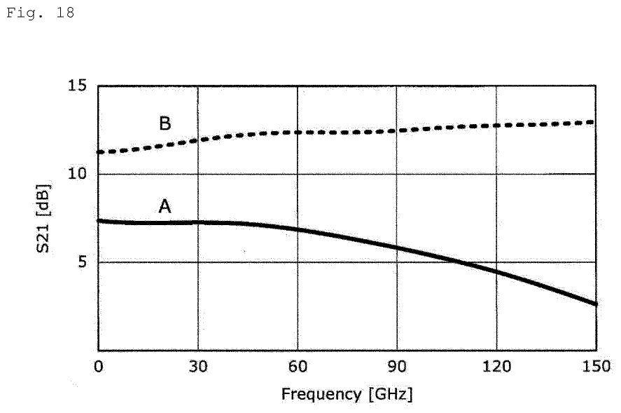

### DETAILED DESCRIPTION OF ILLUSTRATIVE EMBODIMENTS

Embodiments of the present invention will be described next with reference to the drawings.

### First Embodiment

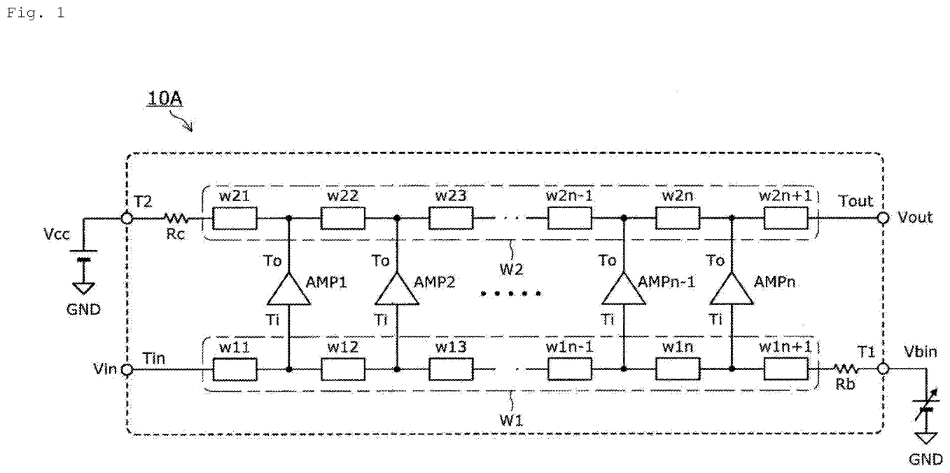

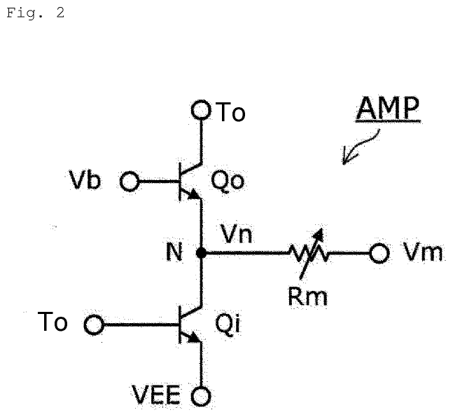

First, a distributed amplifier 10A according to a first embodiment of the present invention will be described with reference to FIGS. 1 and 2. FIG. 1 is a block diagram showing the configuration of a distributed amplifier according to a first embodiment. FIG. 2 is a circuit diagram showing a configuration of a unit amplifier according to the first embodiment.

A distributed amplifier 10A is used in high frequency signal processing circuits of various systems, such as a system for high-speed communication such as optical communication and a radio communication system such as a high-resolution radar, and is a wide-band amplifier having excellent amplification characteristics in a wide frequency band.

As shown in FIG. 1, the distributed amplifier 10A includes, as a main circuit part, an input side transmission line W1, an output side transmission line W2, an input side terminating resistance Rb, an output side terminating resistance Rc, and n (n is an integer of 2 or more) unit amplifiers AMP (AMP1, AMP2, . . . , AMPn−1, and AMPn).

### Input Side Transmission Line

The input side transmission line W1 has a configuration in which n+1 unit transmission lines w11, w12, . . . , w1n, and w1n+1 made up of high frequency transmission lines such as a coplanar waveguide (CPW) are connected in series. An input signal Vin is input to one end of a low-frequency side (unit transmission line w11) of the input side transmission line W1 via an input terminal Tin.

### Output Side Transmission Line

The output side transmission line W2 has a configuration in which n+1 unit transmission lines w21, w22, . . . , w2n, and w2n+1 made up of high frequency transmission lines such as a coplanar waveguide are connected in series, like the input side transmission line W1. An output signal Vout obtained by amplifying the input signal Vin is output from the other end of the high-frequency side (unit transmission line w2n+1) of the output side transmission line W2 via an output terminal Tout.

### Input Side Terminating Resistance

One end of the input side terminating resistance Rb is connected to the other end of the high-frequency side (unit transmission line w1n+1) of the input side transmission line W1, and the other end is connected to a connecting terminal T1 to which a DC bias voltage Vbin is applied. The resistance value of the input side terminating resistance Rb is 50Ω, as in the case of a general high-frequency transmission line.

### Output Side Terminating Resistance

One end of the output side terminating resistance Re is connected to one end of the low-frequency side (unit transmission line w21) of the output side transmission line W2, and the other end is connected to a connecting terminal T2 to which a DC power supply voltage Vcc is applied. The resistance value of the output side terminating resistance Re is 50Ω, as in the case of a general high-frequency transmission line.

### Unit Amplifier

The unit amplifiers AMP (AMP1, AMP2, . . . , AMPn−1, and AMPn) are also called unit cells and are disposed parallel to each other in a ladder shape along the input side transmission line W1 and the output side transmission line W2. A cell input terminal Ti is connected to the input side transmission line W1 and a cell output terminal To is connected to the output side transmission line W2. Specifically, the cell input terminal Ti of the unit amplifier AMP1 is connected to a connecting point between the unit transmission line w11 and the unit transmission line w12 of the input side transmission line W1, and the cell output terminal To of the unit amplifier AMP1 is connected to a connecting point between the unit transmission line w21 and the unit transmission line w22 of the output side transmission line W2. The cell input terminal Ti of the unit amplifier AMPn is connected to a connecting point between the unit transmission line win and the unit transmission line w1n+1 of the input side transmission line W1, and the cell output terminal To of the unit amplifier AMPn is connected to a connecting point between the unit transmission line w2n and the unit transmission line w2n+1 of the output side transmission line W2.

Therefore, an input signal Vin input from the input terminal Tin is successively input to the unit amplifier AMP via the input side transmission line W1 in a traveling wave manner. The amplified signals output from the unit amplifiers AMP are synthesized in the same phase via the output side transmission line W2 and output from an output terminal Tout as an output signal Vout. Thus, since a pseudo distributed constant line is formed by the capacitance components of the unit amplifier AMP and the inductor components of the input side transmission line W1 and the output side transmission line W2, the wide band characteristic of the distributed amplifier 10A is realized.

As shown in FIG. 2, the unit amplifier AMP is made up of a cell having first and second transistors Qi and Qo (cascode circuit), which are cascode-connected, and a variable resistance circuit Rm. Although a case where the first and second transistors Qi and Qo are constituted by a NPN type bipolar transistor will be described as an example below, a PNP type bipolar transistor may be used, or a MOSFET may be used as will be described later. In the case of the MOSFET, a gate terminal, a drain terminal, and a source terminal correspond to a base terminal, an emitter terminal, and a collector terminal of the bipolar transistor.

The base terminal of the first transistor Qi is connected to the cell input terminal Ti, a negative side power supply voltage VEE is applied to the emitter terminal, and the collector terminal is connected to the emitter terminal of the second transistor Qo at the connecting point N.

The collector terminal of the second transistor Qo is connected to the cell output terminal To, the bias voltage Vb is applied to the base terminal, and the emitter terminal is connected to the collector terminal of the first transistor Qi via the connecting point N.

### Variable Resistance Circuit

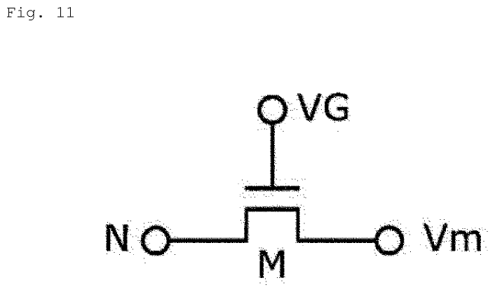

As shown in FIG. 2, one end of the variable resistance circuit Rm is connected to the connecting point N, and a set voltage Vm is applied to the other end. At this time, a set voltage Vm having a DC voltage value equal to the DC potential Vn of the connecting point N is applied to the other end of the variable resistance circuit Rm. The variable resistance circuit Rm may be constituted by, for example, a MOSFET shown in FIG. 11 which will be described later.

### Principles of Embodiments of the Present Invention

Principles of embodiments of the present invention will be described next. As shown in FIG. 2, if a circuit configuration in which the set voltage Vm is applied to the connecting point N of the cascode-connected two transistors Qi and Qo via the variable resistance circuit Rm is used, the gain of the unit amplifier AMP can be changed by adjusting the resistance value of the variable resistance circuit Rm. At this time, there are cases where the band characteristic of the unit amplifier AMP may be deteriorated by adjusting the resistance value of the variable resistance circuit Rm. This is because the DC potential Vn of the connecting point N is changed by the change of the resistance value of the variable resistance circuit Rm, and the bias condition of the unit amplifier AMP is changed.

In embodiments of the present invention, attention is paid to such a fact that the deterioration of the band characteristic of the unit amplifier AMP is caused by a change in the DC potential Vn of the connecting point N, and a DC voltage equal to the DC potential Vn of the connecting point N is applied to the other end of the variable resistance circuit Rm, as the set voltage Vm. Thus, even if the resistance value of the variable resistance circuit Rm is adjusted, since the DC potential Vn of the connecting point N is maintained and the bias condition of the unit amplifier AMP is maintained, the gain can be changed, without significantly degrading band characteristics.

When the set voltage Vm is adjusted in actual use, first, a voltmeter of high impedance is connected to the other end of the variable resistance circuit Rm instead of the set voltage Vm, and the DC voltage Vn of the connecting point N is measured through the variable resistance circuit Rm. Next, the measured voltage value is set to the voltage source of the set voltage Vm, and finally, the voltmeter is removed and the set voltage Vm output from the voltage source may be applied to the other end of the variable resistance circuit Rm. The adjustment method may automatically switch the voltmeter and the voltage source inside the voltage source device, using the voltage source device having the voltmeter.

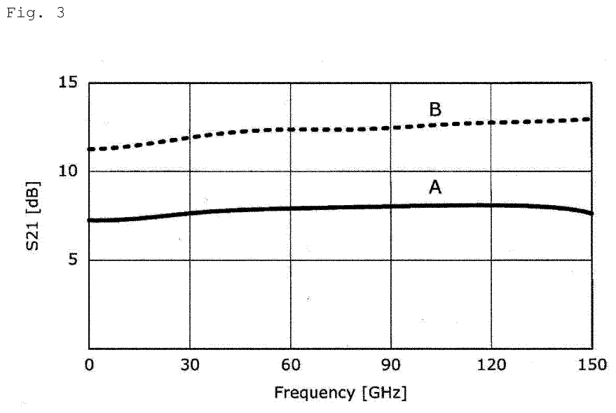

FIG. 3 is a graph showing the simulation result of the S parameter S21 of the unit amplifier according to the first embodiment, and the characteristic A shows the low gain setting time and the characteristic B shows the high gain setting time. Thus, even when the resistance value of the variable resistance circuit Rm is adjusted and the gain of the unit amplifier AMP is switched between a high gain and a low gain, since the set voltage Vm is adjusted, it can be seen that the gain can be changed without greatly deteriorating the band characteristic, as shown in FIG. 3.

As described above, the present embodiment is configured to include a variable resistance circuit Rm whose one end is connected to the connecting point N of the cascode-connected first and second transistors in the unit amplifier AMP, to apply a set voltage Vm made up of a DC voltage value equal to the DC potential Vn of the connecting point N to the other end of the variable resistance circuit Rm.

Thus, even if the resistance value of the variable resistance circuit Rm is adjusted to change the gain of the unit amplifier AMP, the DC potential Vn of the connecting point N is maintained, and the bias condition of the unit amplifier AMP is maintained. Therefore, the gain can be changed without largely deteriorating the band characteristic.

### Second Embodiment

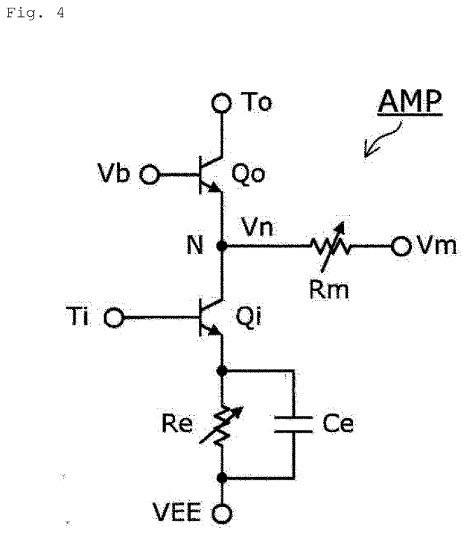

Next, a distributed amplifier 10B according to a second embodiment of the present invention will be described with reference to FIG. 4. FIG. 4 is a circuit diagram showing a configuration of a unit amplifier according to the second embodiment.

In order to compensate for loss of passive components when mounting, a variable peaking function may be required in addition to a variable gain function. In this embodiment, an RC parallel circuit is added to the circuit configuration of the unit amplifier AMP shown in FIG. 2 among the distributed amplifier 10A according to the first embodiment shown in FIG. 1.

Specifically, as shown in FIG. 4, the RC parallel circuit is made up of a circuit in which a variable resistive element Re and a capacitance element Ce are connected in parallel, one end of which is connected to the emitter terminal of the first transistor Qi, and the other end of which is supplied with a negative side power supply voltage VEE. Other configurations of the distributed amplifier 10B according to the present embodiment are the same as those of the distributed amplifier 10A of FIG. 1, and a detailed description thereof will be omitted here.

Thus, the function of variable gain and variable peaking can be independently realized in the unit amplifier AMP. Specifically, a peaking amount (difference between DC gain and maximum gain) can be adjusted by changing the resistance value of the variable resistive element Re. At this time, when the resistance value of the variable resistive element Re is changed, the voltage value of the negative side power supply voltage VEE is also adjusted so that the current amount of the unit amplifier AMP becomes constant.

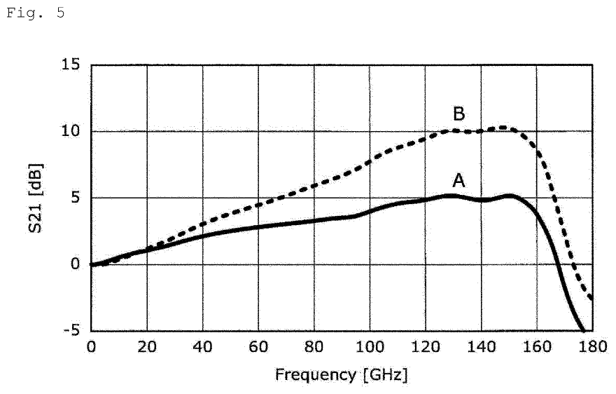

FIG. 5 is a graph showing the simulation result of the S parameter S21 of the unit amplifier according to the second embodiment, in which the characteristic A indicates the low peaking setting time and the characteristic B indicates the high peaking setting time. These characteristics A and B indicate characteristics obtained by standardizing the S parameter S21 with a gain of 1 GHz. Thus, even when the resistance value of the variable resistive element Re is changed and the peaking amount of the unit amplifier AMP is adjusted, it can be seen that the peaking amount can be adjusted, without generating ripples in frequency characteristics, as shown in FIG. 5. In the circuit configuration of the unit amplifier AMP according to the present embodiment, the peaking frequency can be adjusted by making the capacitance element Ce variable.

### Third Embodiment

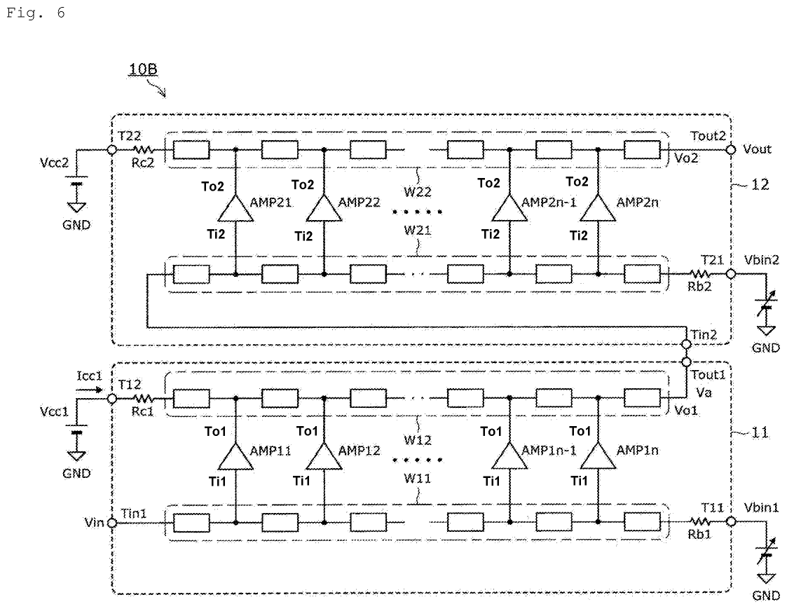

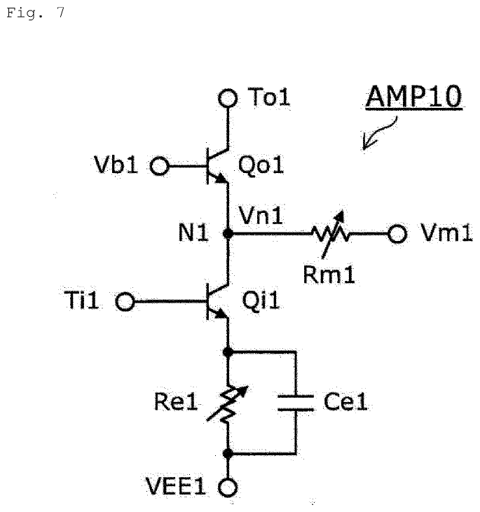

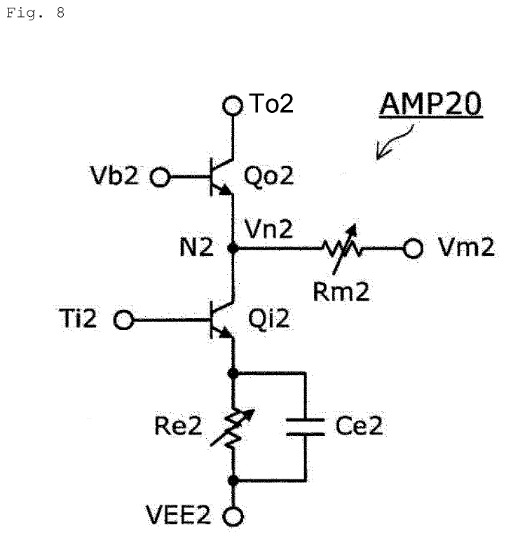

Next, a distributed amplifier 10C according to a third embodiment of the present invention will be described with reference to FIG. 6. FIG. 6 is a block diagram showing the configuration of the distributed amplifier according to the third embodiment. FIG. 7 is a circuit diagram showing a configuration of a unit amplifier (front amplifier block) according to the third embodiment. FIG. 8 is a circuit diagram showing a configuration of a unit amplifier (rear amplifier block) according to the third embodiment.

As shown in FIG. 6, the distributed amplifier 10C according to this embodiment is constituted by cascade-connecting two front amplifier blocks 11 and rear amplifier blocks 12 made up of the distributed amplifier 10A according to the first embodiment shown in FIG. 1. The front amplifier block 11 and the rear amplifier block 12 may be a distributed amplifier 10B according to the second embodiment.

### Front Amplifier Block

As shown in FIG. 7, the front amplifier block 11 is configured to amplify an input signal Vin input from an input terminal Tin1 and output an obtained intermediate signal Va from an output terminal Tout1. The front amplifier block 11 includes, as main circuit parts, an input side transmission line W11, an output side transmission line W12, an input side terminating resistance Rb1, an output side terminating resistance Rc1, and n (n is an integer of 2 or more) unit amplifiers AMP10 (AMP11, AMP12, . . . , AMP1n−1, and AMP1n). These correspond to each of the input side transmission line W1, the output side transmission line W2, the input side terminating resistance Rb, the output side terminating resistance Re, and n (n is an integer of 2 or more) unit amplifiers AMP of FIG. 1.

### Input Side Transmission Line

An input signal Vin is input to one end of the low-frequency side of the input side transmission line W11 via an input terminal Tin1. A DC bias voltage Vbin1 is applied to the other end of the high-frequency side of the input side transmission line W11 via a connecting terminal T11 and an input side terminating resistance Rb1. The resistance value of the input side terminating resistance Rb1 is 50Ω, similarly to the case of a general high-frequency transmission line.

### Output Side Transmission Line

A DC power supply voltage Vcc1 is applied to one end on the low-frequency side of the output side transmission line W12 via a connecting terminal T12 and an output side terminating resistance Rc1. An intermediate signal Va obtained by amplifying the input signal Vin is output from the other end of the high-frequency side of the output side transmission line W2 via an output terminal Tout1.

### Unit Amplifier

The unit amplifiers AMP10 are called unit cells and are disposed in parallel with each other along the input side transmission line W11 and the output side transmission line W12 in a ladder shape. A cell input terminal Ti1 is connected to the input side transmission line W11, and a cell output terminal To1 is connected to the output side transmission line W12.

As shown in FIG. 7, the unit amplifier AMP10 is made up of a cell having first and second transistors Qi1 and Qo1 (cascode circuit), which are cascode-connected, and a variable resistance circuit Rm1. These correspond to each of the cascode-connected first and second transistors Qi and Qo and the variable resistance circuit Rm of FIG. 2.

A base terminal of the first transistor Qi1 is connected to a cell input terminal Ti1, and a collector terminal is connected to an emitter terminal of the second transistor Qo1 at a connecting point N1. A negative side power supply voltage VEE1 is applied to an emitter terminal of the first transistor Qi1 via an RC parallel circuit in which a variable resistive element Re1 and a capacitive element Ce1 are connected in parallel, similarly to FIG. 4.

In the second transistor Qo1, a collector terminal is connected to the cell output terminal To1, a bias voltage Vb1 is applied to a base terminal, and an emitter terminal is connected to the collector terminal of the first transistor Qi1 via the connecting point N1.

### Variable Resistance Circuit

As shown in FIG. 7, one end of the variable resistance circuit Rm1 is connected to the connecting point N1, and the setting voltage Vm1 is applied to the other end. At this time, a set voltage Vm2 including a DC voltage value equal to a DC potential Vn1 of the connecting point N1 is applied to the other end of the variable resistance circuit Rm1. The variable resistance circuit Rm1 may be constituted by, for example, a MOSFET shown in FIG. 11 which will be described later.

When the set voltage Vm1 is adjusted in actual use, first, similarly to the first embodiment, a voltmeter of high impedance is connected to the other end of the variable resistance circuit Rm1 in place of the set voltage Vm1, and the DC voltage of the connecting point N1 is measured via the variable resistance circuit Rm1. Next, the measured voltage value is set as a voltage source of the set voltage Vm1, and finally, the voltmeter is detached, and the set voltage Vm1 output from the voltage source may be applied to the other end of the variable resistance circuit Rm1. This adjustment method may automatically switch the voltmeter and the voltage source inside the voltage source device, using the voltage source device equipped with the voltmeter.

### Rear Amplifier Block

As shown in FIG. 8, the rear amplifier block 12 is configured to amplify the intermediate signal Va from the front amplifier block 11 input from the input terminal Tin2 and output the obtained output signal Vout from the output terminal Tout2. The rear amplifier block 12 includes, as main circuit parts, an input side transmission line W21, an output side transmission line W22, an input side terminating resistance Rb2, an output side terminating resistance Rc2, and n (n is an integer of 2 or more) unit amplifiers AMP20 (AMP21, AMP22, . . . , AMP2n−1, and AMP2n). These correspond to each of the input side transmission line W1, the output side transmission line W2, the input side terminating resistance Rb, the output side terminating resistance Rc, and n (n is an integer of 2 or more) unit amplifiers AMP of FIG. 1.

### Input Side Transmission Line

An intermediate signal Va is input to one end of the low-frequency side of the input side transmission line W21 via the input terminal Tin2. A DC bias voltage Vbin 2 is applied to the other end of the high-frequency side of the input side transmission line W21 via a connecting terminal T21 and an input side terminating resistance Rb2. The resistance value of the input side terminating resistance Rb2 is 50Ω, similarly to the case of a general high frequency transmission line.

### Output Side Transmission Line

A DC power supply voltage Vcc2 is applied to one end of the low-frequency side of the output side transmission line W22 via a connecting terminal T22 and an output side terminating resistance Rc2. An output signal Vout obtained by amplifying the intermediate signal Va is output from the other end of the high-frequency side of the output side transmission line W22 via an output terminal Tout2.

### Unit Amplifier

The unit amplifiers AMP 20 are called unit cells and are disposed in parallel with each other along the input side transmission line W21 and the output side transmission line W22 in a ladder shape. A cell input terminal Ti2 is connected to the input side transmission line W21, and a cell output terminal To2 is connected to the output side transmission line W22.

As shown in FIG. 8, the unit amplifier AMP 20 is made up of a cell having first and second transistors Qi2 and Qo2 [cascode circuit] cascode-connected and a variable resistance circuit Rm2. These transistors correspond to each of the cascode-connected first and second transistors Qi and Qo and the variable resistance circuit Rm of FIG. 2.

A base terminal of the first transistor Qi2 is connected to a cell input terminal Ti2, and a collector terminal is connected to an emitter terminal of the second transistor Qo2 at a connecting point N2. A negative side power supply voltage VEE2 is applied to an emitter terminal of the first transistor Qi2 via an RC parallel circuit in which a variable resistive element Re2 and a capacitive element Ce2 are connected in parallel, similarly to FIG. 4.

In the second transistor Qo2, a collector terminal is connected to the cell output terminal To2, a bias voltage Vb2 is applied to a base terminal, and the emitter terminal is connected to the collector terminal of the first transistor Qi2 via the connecting point N2.

### Variable Resistor Circuit

As shown in FIG. 8, one end of the variable resistance circuit Rm2 is connected to the connecting point N2, and the set voltage Vm2 is applied to the other end. At this time, a set voltage Vm2 including a DC voltage value equal to a DC potential Vn2 of the connecting point N2 is applied to the other end of the variable resistance circuit Rm2. The variable resistance circuit Rm may be constituted by, for example, a MOSFET shown in FIG. 11 which will be described later.

When the set voltage Vm2 is adjusted in actual use, similarly to the first embodiment, first, a voltmeter of high impedance is connected to the other end of the variable resistance circuit Rm2 in place of the set voltage Vm2, and the DC voltage of the connecting point N2 is measured via the variable resistance circuit Rm2. Next, the measured voltage value is set as a voltage source of a set voltage Vm2, and finally, the voltmeter is detached, and the set voltage Vm2 output from the voltage source may be applied to the other end of the variable resistance circuit Rm2. This adjustment method may automatically switch the voltmeter and the voltage source inside the voltage source device, using the voltage source device equipped with the voltmeter.

### Adjustment of Bias Condition

In the configuration shown in FIG. 6 in which the front amplifier block 11 and the rear amplifier block 12 are cascade-connected as in this embodiment, if the bias conditions of the front amplifier block 11 and the rear amplifier block 12 are different, band deterioration occurs in the distributed amplifier 10B. In the present embodiment, the power supply voltage Vcc1 indicating the voltage, in which the DC potential Vo1 of the output terminal Tout1 of the front amplifier block 11 becomes equal to the bias voltage Vbin2 of the rear amplifier block 12, is applied to the output side transmission line W12 of the front amplifier block 11, focusing on the fact that the band deterioration is caused by the DC current flowing through the input side transmission line W21 of the rear amplifier block 12.

When the power supply voltage Vcc1 is adjusted at the time of actual use, first, a DC current Icc1 flowing from the power supply voltage Vcc1 to the output side transmission line W12 via the terminating resistance Rc1 is measured by an ammeter in the front amplifier block 11, and the DC potential Vo1 of the output terminal Tout1 of the front amplifier block 11 is calculated. When the resistance value of the terminating resistance Rc1 is R (generally, R=50Ω), the DC potential Vo1 is obtained by Vo1=Vcc1+Icc1×R. Next, the obtained DC potential Vo1 is compared with the voltage value of the bias voltage Vbin2 measured by a voltmeter, and the voltage value of the power supply voltage Vcc1 may be adjusted so that the DC potential Vo1 becomes equal to the voltage value of the bias voltage Vbin2.

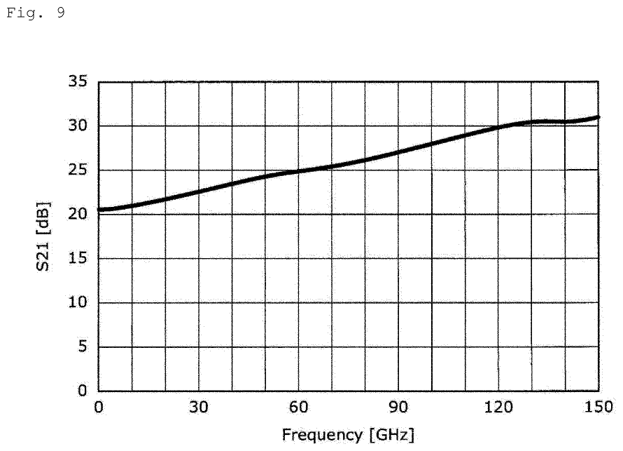

Thus, the voltage value of the power supply voltage Vcc1 is adjusted to equalize the bias conditions of the front amplifier block 11 and the rear amplifier block 12, thereby preventing the deterioration of the band characteristics as shown in FIG. 9. FIG. 9 is a graph showing simulation results of the S parameter S21 of the unit amplifier according to the third embodiment. Further, it is understood that a higher gain and a higher peaking amount can be realized by the configuration in which the front amplifier block 11 and the rear amplifier block 12 are cascade-connected, as compared with the above-mentioned FIGS. 3 and 5.

### Fourth Embodiment

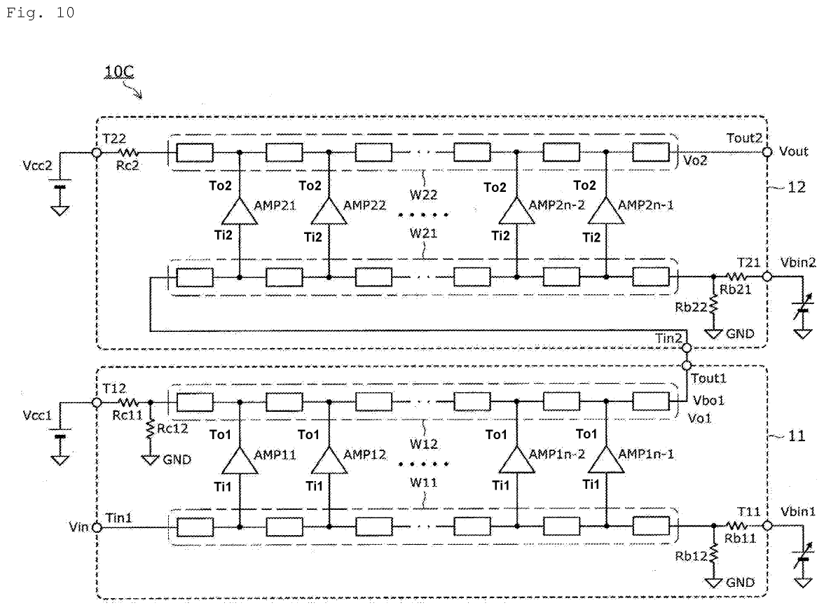

Next, a distributed amplifier 10C according to the present embodiment will be described with reference to FIG. 10. FIG. 10 is a block diagram showing the configuration of a distributed amplifier according to a fourth embodiment.

In the configuration shown in FIG. 6 described above, the example in which the input side terminating resistance Rb1 and the output side terminating resistance Rc1 of the front amplifier block 11 and the input side terminating resistance Rc2 of the rear amplifier block 12 are constituted by single resistive elements has been described. However, when the wiring from the terminating resistances Rb1, Rc1, and Rb2 to the pads of the respective connecting terminals T11, T12, and T21 is long, there is a likelihood that reflection characteristics on the high-frequency side may be deteriorated.

In this embodiment, a case where any one or all of these terminating resistances Rb1, Rc1, and Rb2 are configured by a resistance parallel circuit in which two resistive elements are connected in parallel will be described. In the distributed amplifier 10C according to the present embodiment, other configurations except for the terminating resistances Rb1, Rc1, and Rb2 are the same as those of FIG. 6, and a detailed description thereof will not be provided.

In the distributed amplifier 10C according the present embodiment, a resistance parallel circuit including a resistive element Rb11 and a resistive element Rb12 is connected to the other end of the high-frequency side of the input side transmission line W11 of the front amplifier block 11 in place of the input side terminating resistance Rb1. One end of the resistive element Rb11 is connected to the other end of the high-frequency side of the input side transmission line W11, and a bias voltage Vbin 1 is applied to the other end via the connecting terminal T11. One end of the resistive element Rb12 is connected to the other end of the high-frequency side of the input side transmission line w11, and the other end is connected to a ground potential GND. A combined resistance of these resistive elements Rb11 and Rb12 is 50Ω similarly to the terminating resistance Rb1. In this case, the resistance value of the resistive element Rb12 may be set to be smaller than the resistance value of the resistive element Rb11.

A resistance parallel circuit including a resistive element Rc11 and a resistive element Rc12 is connected to one end of the low-frequency side of the output side transmission line W12 of the front amplifier block 11 in place of the output side terminating resistance Rc1. One end of the resistive element Rc1 is connected to one end on the low-frequency side of the output side transmission line W12, and a power supply voltage Vcc1 is applied to the other end via the connecting terminal T12. One end of the resistive element Rc12 is connected to one end on the low-frequency side of the output side transmission line W12, and the other end is connected to the ground potential GND. The combined resistance of these resistive elements Rc11 and Rc12 is 50Ω similarly to the terminating resistance Rc1. In this case, the resistive element Rc12 may have a resistance value smaller than the resistance value of the resistive element Rc11.

A resistance parallel circuit including a resistive element Rb21 and a resistive element Rb22 is connected to the other end of the high-frequency side of the input side transmission line W21 of the rear amplifier block 12 in place of the input side terminating resistance Rb2. One end of the resistive element Rb21 is connected to the other end of the high-frequency side of the input side transmission line W21, and a bias voltage Vbin2 is applied to the other end via the connecting terminal T21. One end of the resistive element Rb22 is connected to the other end of the high-frequency side of the input side transmission line W21, and the other end is connected to the ground potential GND. The combined resistance of these resistive elements Rb21 and Rb22 is 50Ω similarly to the terminating resistance Rb2. In this case, the resistive element Rb22 may have a resistance value smaller than the resistance value of the resistive element Rb21.

In this way, in this embodiment, any or all of the terminating resistances Rb1, Rc1, and Rb2 are constituted of a resistance parallel circuit in which two resistive elements are connected in parallel. Thus, the other end of the high-frequency side of the input side transmission line W11, one end on the low-frequency side of the output side transmission line W12, and the other end of the high-frequency side of the input side transmission line W21 are connected to the ground potential GND via the resistive elements Rb12, Rc12, and Rb22. Therefore, even when the wiring from resistive elements Rb11, Rc11, and Rb21 to the pads of the connecting terminals T11, T12, and T21 is long, deterioration of reflection characteristics of the high-frequency side can be suppressed. Further, the deterioration suppressing effect of the reflection characteristics can be enhanced, by making the resistance values of the resistive elements Rb12, Rc12, and Rb22 lower than the resistance values of the respective resistive elements Rb11, Rc11, and Rb21.

### Fifth Embodiment

Next, a distributed amplifier according to a fifth embodiment of the present invention will be described with reference to FIG. 11. FIG. 11 is a circuit diagram showing a variable resistance circuit according to the fifth embodiment.

The variable resistance circuit Rm of the unit amplifier AMP in the above-mentioned first and fourth embodiments may be formed of a MOSFET as shown in FIG. 11. If the manufacturing process of the distributed amplifier is a process capable of manufacturing a MOSFET, it can be easily realized.

Specifically, for example, in the case of the unit amplifier AMP shown in FIG. 2, one of a drain terminal and a source terminal of the MOSFET is connected to the connecting point N, and the set voltage Vm may be applied to the other of the drain terminal and the source terminal. Then, an adjustment voltage VG including a DC voltage value for adjusting the gain corresponding to the resistance value of the variable resistance circuit Rm may be applied to the gate terminal. Therefore, it is possible to realize the variable resistance circuit Rm with a simple circuit configuration. This configuration is also similarly applicable to the unit amplifier AMP, AMP 10, and AMP 20 of FIGS. 4, 7, and 8.

### Sixth Embodiment

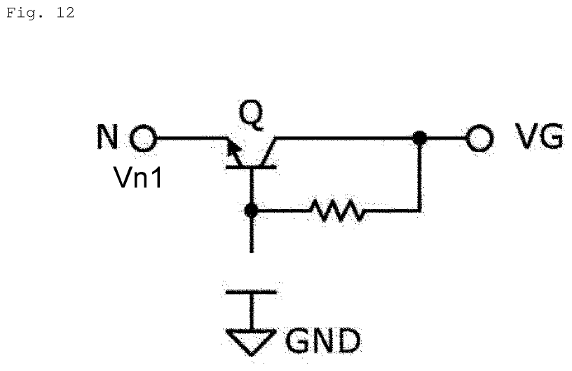

Next, a distributed amplifier according to a sixth embodiment of the present invention will be described with reference to FIG. 12. FIG. 12 is a circuit diagram showing a variable resistance circuit according to the sixth embodiment.

The variable resistance circuit Rm of the unit amplifier AMP in the above-mentioned first and fourth embodiments may be formed of a bipolar transistor as shown in FIG. 12. Even when the manufacturing process of the distributed amplifier is a process capable of manufacturing only bipolar transistors, it can be easily realized.

Specifically, in the case of the unit amplifier AMP shown in FIG. 2, the emitter terminal of the NPN type bipolar transistor Q is connected to the connecting point N, and an adjustment voltage VG including a DC voltage value for adjusting the gain corresponding to the resistance value of the variable resistance circuit Rm may be applied to the collector terminal. A resistive element is connected between the base terminal and the emitter terminal of the bipolar transistor Q, and the base terminal may be grounded to an installation potential GND via the capacitive element. Thus, when the adjustment voltage VG is changed to a voltage value higher than the potential Vn of the connecting point N, the resistance value of the variable resistance circuit Rm is lowered, and the gain of the unit amplifier AMP can be reduced. Therefore, the variable resistance circuit Rm can be realized with an extremely simple circuit configuration. It is also similarly applicable to the unit amplifiers AMP, AMP10, and AMP20 of FIGS. 4, 7, and 8 described above.

Thus, even when the resistance value of the variable resistance circuit Rm is adjusted and the gain of the unit amplifier AMP is switched between a high gain and a low gain, gain can be changed without significantly deteriorating band characteristics, as shown in FIG. 3.

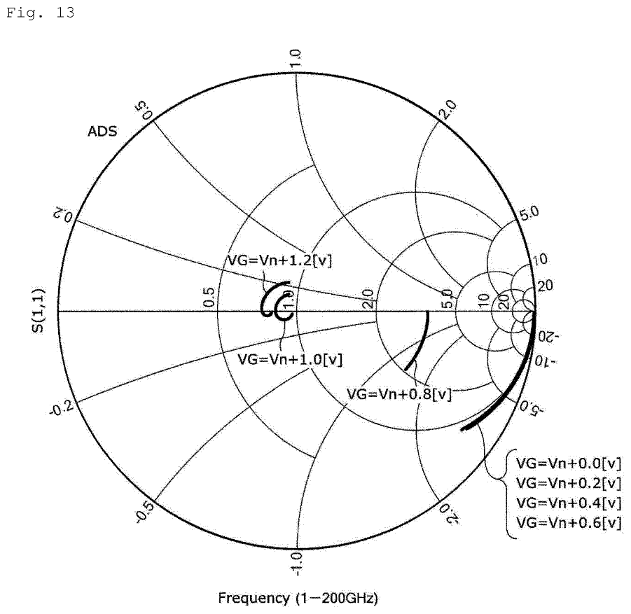

FIG. 13 is a Smith chart showing simulation results of the S parameter S11 viewed from the connecting point N of the variable resistance circuit according to the sixth embodiment. Here, the change in the input impedance Zin of the variable resistance circuit Rm viewed from the connecting point N side when changing the voltage value of the adjustment voltage VG is shown to be normalized by 50Ω. Thus, it can be confirmed that the resistance value of Zin can be changed by the voltage value of the adjustment voltage VG.

### Seventh Embodiment

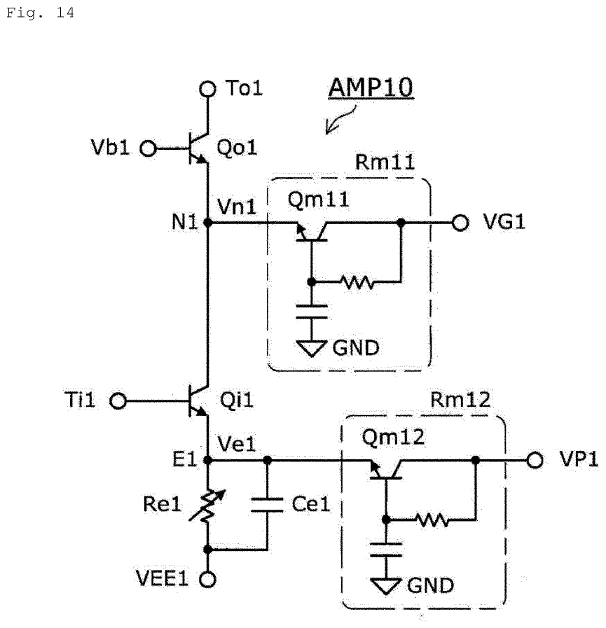

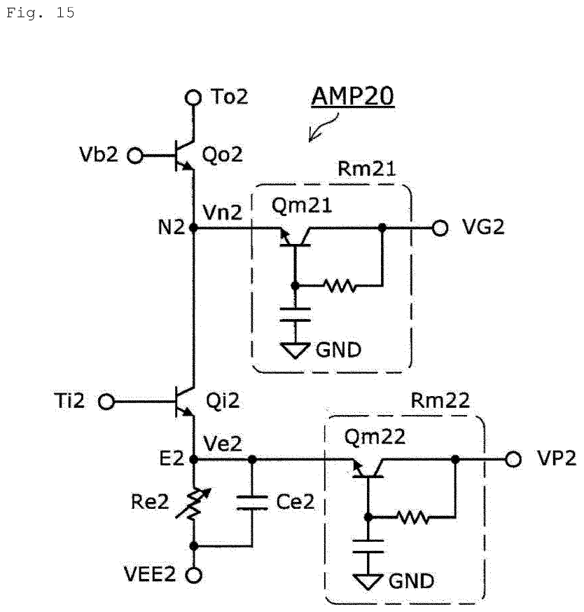

Next, a distributed amplifier according to a seventh embodiment of the present invention will be described with reference to FIGS. 14 and 15. FIG. 14 is a circuit diagram showing a configuration of a unit amplifier (front amplifier block) according to the seventh embodiment. FIG. 15 is a circuit diagram showing a configuration of a unit amplifier (rear amplifier block) according to the seventh embodiment.

In this embodiment, a case in which the distributed amplifier 10B or 10C of FIG. 6 or 10 described above and the variable resistance circuits Rm1 and Rm2 of FIG. 7 and FIG. 8 are constituted by the variable resistance circuits of FIG. 12 to adjust the gain will be described. In this case, in the present embodiment, another variable resistance circuit of FIG. 12 may be added to each of the unit amplifiers AMP10 and AMP20 to make the gain and the peaking amount individually adjustable.

### Unit Amplifier of Front Amplifier Block

As shown in FIG. 14, in the unit amplifier AMP10 of the front amplifier block 11 according to the embodiment, instead of the variable resistance circuit Rm1 of FIG. 7 described above, a variable resistance circuit Rm11 for gain adjustment having the configuration of FIG. 12 described above is connected to a connecting point N1 between the input transistor Qi1 and the output transistor Qo1. A variable resistance circuit Rm12 for peaking amount adjustment having the configuration shown in FIG. 12 is newly connected to the emitter terminal of the input transistor Qi1.

### Variable Resistance Circuit for Gain Adjustment

As shown in FIG. 14, the variable resistance circuit Rm11 for gain adjustment is made up of a transistor Qm11 of an NPN type bipolar transistor in which an emitter terminal is connected to the connecting point N1, and an adjustment voltage VG1 (first adjustment voltage) made up of a DC voltage value for adjusting a gain is applied to a collector terminal. A base terminal of the transistor Qm11 is grounded to a ground potential GND via a capacitive element and connected to a collector terminal of the transistor Qm11 via a resistive element.

When the adjustment voltage VG1 is set to a voltage value higher than the potential Vn1 of the connecting point N1, the resistance value of the variable resistance circuit Rm11 is lowered, and the gain of the unit amplifier AMP10 can be reduced. At this time, the DC potential Vo1 of the intermediate signal Va output from the front amplifier block 11 is changed, and the bias conditions of the front amplifier block 11 and the rear amplifier block 12 become different.

Therefore, the DC potential Vo1 may be adjusted to a voltage value equal to the bias voltage Vbin2, by adjusting the power supply voltage Vcc1 in the same manner as the adjustment of the bias condition described in the third embodiment. Thus, bias conditions of the front amplifier block 11 and the rear amplifier block 12 become equal, and band deterioration in the distributed amplifier can be suppressed.

### Variable Resistance Circuit for Peaking Amount Adjustment

As shown in FIG. 14, the variable resistance circuit Rm12 for peaking amount adjustment is made up of an NPN type bipolar transistor Qm12 in which an emitter terminal is connected to the emitter terminal of the input transistor Qi1, and an adjustment voltage VP1 (second adjustment voltage) made up of a DC voltage value for peaking amount adjustment is applied to a collector terminal. A base terminal of the transistor Qm12 is grounded to the ground potential GND via the capacitive element and connected to the collector terminal of the transistor Qm12 via the resistive element.

When the adjustment voltage VP1 is set to a voltage value higher than the potential Ve1 of the emitter terminal of the input transistor Qi1, the resistance value of the variable resistance circuit Rm12 is lowered, and the peaking amount can be reduced. At this time, since the value of the current flowing through the unit amplifier AMP10 is lowered, the negative side power supply voltage VEE1 may be adjusted so that the original current value is maintained.

### Unit Amplifier of Rear Amplifier Block

As shown in FIG. 15, in the unit amplifier AMP20 of the rear amplifier block 12 according to the embodiment, a variable resistance circuit Rm21 for gain adjustment having the configuration shown in FIG. 12 is connected to a connecting point N2 between an input transistor Qi2 and an output transistor Qo2 which are cascode-connected, in place of the variable resistance circuit Rm2 of the configuration shown in FIG. 8. A variable resistance circuit Rm22 for peaking amount adjustment having the configuration shown in FIG. 12 is newly connected to the emitter terminal of the input transistor Qi2.

### Variable Resistance Circuit for Gain Adjustment

As shown in FIG. 15, the variable resistance circuit Rm21 for gain adjustment is made up of an NPN type bipolar transistor Qm21 in which an emitter terminal is connected to the connecting point N2, and an adjustment voltage VG2 (first adjustment voltage) made up of a DC voltage value for adjusting a gain is applied to a collector terminal. A base terminal of the transistor Qm21 is grounded to the ground potential GND via the capacitive element and connected to the collector terminal of the transistor Qm21 via the resistive element.

When the adjustment voltage VG2 is set to a voltage value higher than the potential Vn2 of the connecting point N2, the resistance value of the variable resistance circuit Rm21 is lowered, and the gain of the unit amplifier AMP20 can be reduced. At this time, although the DC potential Vo2 of the output signal Vout output from the rear amplifier block 12 changes, since the bias conditions of the front amplifier block 11 and the rear amplifier block 12 are not affected, the adjustment of the power supply voltage Vcc2 is not required.

### Variable Resistance Circuit for Peaking Amount Adjustment

As shown in FIG. 15, the variable resistance circuit Rm22 for peaking amount adjustment is made up of an NPN type bipolar transistor Qm22 in which an emitter terminal is connected to the emitter terminal of the input transistor Qi2 and an adjustment voltage VP2 (second adjustment voltage) made up of a DC voltage value for peaking amount adjustment is applied to the collector terminal. A base terminal of the transistor Qm22 is grounded to the ground potential GND via the capacitive element and connected to the collector terminal of the transistor Qm22 via the resistive element.

When the adjustment voltage VP2 is set to a voltage value higher than the potential Ve2 of the emitter terminal of the input transistor Qi2, the resistance value of the variable resistance circuit Rm22 is lowered, and the peaking amount can be reduced. In this case, since the current value of the unit amplifier AMP20 is lowered, the negative side power supply voltage VEE2 may be adjusted so that the original current value is maintained.

### Extension of Embodiments

Embodiments of the present invention have been described thus far with reference to exemplary embodiments, but the embodiments of the present invention are not limited to the above embodiments. The configuration and details of embodiments of the present invention can be altered in various manners which can be understood by those skilled in the art within the scope of the present invention. Furthermore, the embodiments can be combined as desired as long as doing so does not produce any conflicts.

### REFERENCE SIGNS LIST

10A, 10B, 10C Distributed amplifier
W1, W11, W21 Input side transmission line
W2, W12, W22 Output side transmission line
Rb, Rb1, Rb2 Input side terminating resistance
Rc, Rc1, Rc2 Output side terminating resistance
Rb11, Rb12, Rb21, Rb22, Rc11, Rc12 Resistive element
AMP, AMP10, AMP20 Unit amplifier
Qi, Qi1, Qi2 Input transistor
Qo, Qo1, Qo2 Output transistor
Rm, Rm1, Rm2, Rm11, Rm12, Rm21, Rm22 Variable resistance circuit
Re, Re1, Re2 Variable resistance element
Ce, Ce1, Ce2 Capacitive element
Vin Input signal
Va Intermediate signal
Vout Output signal
Tin, Tin1, Tin2 Input terminal
Tout, Tout1, Tout2 Output terminal
Ti, Ti1, Ti2Cell Input terminal
To, To1, To2Cell Output terminal
Vbin, Vbin1, Vbin2, Vb, Vb1, Vb2 Bias voltage
Vcc, Vcc1, Vcc2 Power supply voltage
Icc1 Direct current
VEE, VEE1, VEE2 Negative side power supply voltage
Vm, Vm1, Vm2 Set voltage
VG, VG1, VG2, VP1, VP2 Adjustment voltage
Vn, Vn1, Vn2, Vo1, Ve1 DC potential
N, N1, N2 Connecting point
T1, T2, T11, T12, T21, T22 Connecting terminal

1.-8. (canceled)

9. A distributed amplifier comprising:
an input side transmission line configured such that an input signal is input to a first end and an input side terminating resistance is connected to a second end;
an output side transmission line configured such that an output side terminating resistance is connected to a first end and an output signal is output from a second end; and
a plurality of unit amplifiers disposed parallel to each other along the input side transmission line and the output side transmission line in a ladder shape, wherein a cell input terminal is connected to the input side transmission line and a cell output terminal is connected to the output side transmission line, and wherein each of the unit amplifiers comprises:
first and second transistors that are cascode-connected; and
a first variable resistance circuit;
wherein a base terminal or a gate terminal of the first transistor is connected to the cell input terminal;
wherein a collector terminal or a drain terminal of the second transistor is connected to the cell output terminal;
wherein an emitter terminal or a source terminal of the second transistor is connected to the collector terminal or the drain terminal of the first transistor; and
wherein a first end of the first variable resistance circuit is connected to a connecting point of the first and second transistors.

10. The distributed amplifier according to claim 9, wherein each of the unit amplifiers further comprises an RC parallel circuit, wherein a first end of the RC parallel circuit is connected to the emitter terminal or the source terminal of the first transistor and a second end of the RC parallel circuit is configured to be supplied with a negative side power supply voltage.

11. The distributed amplifier according to claim 9, wherein:
the first variable resistance circuit of each unit amplifier comprises a MOSFET;
a drain terminal or a source terminal of the MOSFET is connected to the connecting point;
the other of the drain terminal or the source terminal of the MOSFET is configured to receive a set voltage comprising a DC voltage value equal to a DC potential of the connecting point; and
a gate terminal of the MOSFET is configured to receive a DC voltage for adjustment corresponding to a gain of the unit amplifier.

12. The distributed amplifier according to claim 9, wherein:
the first variable resistance circuit of each unit amplifier comprises a bipolar transistor;
an emitter terminal of the bipolar transistor is connected to the connecting point;
a collector terminal of the bipolar transistor is configured to receive a first adjustment voltage corresponding to a gain of the unit amplifier and having a DC voltage value higher than a DC potential of the connecting point; and
a base terminal of the bipolar transistor is connected to a ground potential via a capacitive element and is connected to the collector terminal of the bipolar transistor via a resistive element.

13. A distributed amplifier comprising:
a front amplifier block configured to amplify an input signal that is input and output an obtained intermediate signal, the front amplifier block comprising a first distributed amplifier; and
a rear amplifier block configured to amplify the intermediate signal output from the front amplifier block and output an obtained output signal, the rear amplifier block comprising a second distributed amplifier;
wherein each of the first distributed amplifier and the second distributed amplifier comprises:
an input side transmission line configured such that an input signal is input to a first end and an input side terminating resistance is connected to a second end;
an output side transmission line configured such that an output side terminating resistance is connected to a first end and an output signal is output from a second end; and
a plurality of unit amplifiers disposed parallel to each other along the input side transmission line and the output side transmission line in a ladder shape, wherein a cell input terminal is connected to the input side transmission line and a cell output terminal is connected to the output side transmission line, and wherein each of the unit amplifiers comprises:
first and second transistors that are cascode-connected; and
a first variable resistance circuit;
wherein a base terminal or a gate terminal of the first transistor is connected to the cell input terminal;
wherein a collector terminal or a drain terminal of the second transistor is connected to the cell output terminal;
wherein an emitter terminal or a source terminal of the second transistor is connected to the collector terminal or the drain terminal of the first transistor; and
wherein a first end of the first variable resistance circuit is connected to a connecting point of the first and second transistors;
wherein a power supply voltage applied to the output side transmission line of the front amplifier block via the output side terminating resistance has a voltage value equal to a sum of a both-end voltage of the output side terminating resistance and a bias voltage applied to the input side transmission line of the rear amplifier block via the input side terminating resistance; and
wherein the both-end voltage comprises a product of a current flowing through the output side terminating resistance and a resistance value of the output side terminating resistance in a case in which a DC potential of an output terminal of the front amplifier block is equal to the bias voltage.

14. The distributed amplifier according to claim 13, wherein:
the input side terminating resistance of the front amplifier block, the output side terminating resistance of the front amplifier block, or the input side terminating resistance of the rear amplifier block comprises a resistance parallel circuit comprises two resistive elements each having a first end connected parallel to respective corresponding transmission lines;
a second end of a first resistive element of the two resistive elements is configured to receive a corresponding DC voltage; and
a second end of a second resistive element of the two resistive elements is connected to a ground potential.

15. The distributed amplifier according to claim 13, wherein each of the unit amplifiers further comprises an RC parallel circuit, wherein a first end of the RC parallel circuit is connected to the emitter terminal or the source terminal of the first transistor and a second end of the RC parallel circuit is configured to be supplied with a negative side power supply voltage.

16. The distributed amplifier according to claim 13, wherein:
the first variable resistance circuit of each unit amplifier comprises a MOSFET;
a drain terminal or a source terminal of the MOSFET is connected to the connecting point;
the other of the drain terminal or the source terminal of the MOSFET is configured to receive a set voltage comprising a DC voltage value equal to a DC potential of the connecting point; and
a gate terminal of the MOSFET is configured to receive a DC voltage for adjustment corresponding to a gain of the unit amplifier.

17. The distributed amplifier according to claim 13, wherein:
the first variable resistance circuit of each unit amplifier comprises a bipolar transistor;
an emitter terminal of the bipolar transistor is connected to the connecting point;
a collector terminal of the bipolar transistor is configured to receive a first adjustment voltage corresponding to a gain of the unit amplifier and having a DC voltage value higher than a DC potential of the connecting point; and
a base terminal of the bipolar transistor is connected to a ground potential via a capacitive element and is connected to the collector terminal of the bipolar transistor via a resistive element.

18. A distributed amplifier comprising:
a front amplifier block configured to amplify an input signal that is input and output an obtained intermediate signal, the front amplifier block comprising a first distributed amplifier; and
a rear amplifier block configured to amplify the intermediate signal output from the front amplifier block and output an obtained output signal, the rear amplifier block comprising a second distributed amplifier;
wherein each of the first distributed amplifier and the second distributed amplifier comprises:
an input side transmission line configured such that an input signal is input to a first end and an input side terminating resistance is connected to a second end;
an output side transmission line configured such that an output side terminating resistance is connected to a first end and an output signal is output from a second end; and
a plurality of unit amplifiers disposed parallel to each other along the input side transmission line and the output side transmission line in a ladder shape, wherein a cell input terminal is connected to the input side transmission line and a cell output terminal is connected to the output side transmission line, and wherein each of the unit amplifiers comprises:
first and second transistors that are cascode-connected; and
a first variable resistance circuit;
wherein a base terminal or a gate terminal of the first transistor is connected to the cell input terminal;
wherein a collector terminal or a drain terminal of the second transistor is connected to the cell output terminal;
wherein an emitter terminal or a source terminal of the second transistor is connected to the collector terminal or the drain terminal of the first transistor; and
wherein a first end of the first variable resistance circuit is connected to a connecting point of the first and second transistors;
wherein a power supply voltage applied to the output side transmission line of the front amplifier block via the output side terminating resistance has a voltage value equal to a sum of a both-end voltage of the output side terminating resistance and a bias voltage applied to the input side transmission line of the rear amplifier block via the input side terminating resistance;
wherein the both-end voltage comprises a product of a current flowing through the output side terminating resistance and a resistance value of the output side terminating resistance in a situation in which a DC potential of an output terminal of the front amplifier block is equal to the bias voltage; and
wherein, in response to a first adjustment voltage being changed at a time of changing a gain, the output side transmission line of the front amplifier block is configured to receive a power supply voltage comprising a new DC voltage value that is equal to a sum of the product of the current flowing through the output side terminating resistance and the resistance value of the output side terminating resistance and the bias voltage applied to the input side transmission line of the rear amplifier block.

19. The distributed amplifier according to claim 18, wherein:
each of the plurality of unit amplifiers of the second distributed amplifier of the rear amplifier block further comprises a second variable resistance circuit;
a first end of the second variable resistance circuit is connected to the emitter terminal or the source terminal of the first transistor; and
a second end of the second variable resistance circuit is configured to receive a second adjustment voltage indicating a DC voltage value corresponding to a peaking amount of the unit amplifier.

20. The distributed amplifier according to claim 19, wherein, in the rear amplifier block, in response to the second adjustment voltage being changed at a time of changing the peaking amount, the emitter terminal or the source terminal of the first transistor is configured to receive a negative side power supply voltage comprising a new DC voltage value for maintaining a constant value of a current flowing through the rear amplifier block via a resistive element.
